(19) United States
(12) Patent Application Publication
(10) Pub. No.: US 2018/0335458 A1
(43) Pub. Date: Nov. 22, 2018

(54) CAPACITANCE SENSOR

(71) Applicant: Cirrus Logic International Semiconductor Ltd., Edinburgh (GB)

(72) Inventors: John L. Melanson, Austin, TX (US); Anindya Bhattacharya, Austin, TX (US); Axel Thomsen, Austin, TX (US); Eric Smith, Austin, TX (US); Vamsikrishna Parupalli, Austin, TX (US); Mark May, Austin, TX (US); Johann Gaboriau, Austin, TX (US); Junsong Li, Austin, TX (US)

(73) Assignee: Cirrus Logic International Semiconductor Ltd., Edinburgh (GB)

(21) Appl. No.: 15/598,582

(22) Filed: May 18, 2017

(51) Int. Cl. G01R 27/26; H03M 3/00

(52) U.S. Cl. CPC G01R 27/2605; H03M 3/458

(57) ABSTRACT

Sensing electronics may be used to measure capacitance of components, such as speakers in mobile devices. A sensing circuit may include a charge-sense front end with sine wave excitation, an analog-to-digital conversion block, and a digital demodulator. The component being measured by the sensing electronics may be excited by a high-frequency sine wave excitation. The digitization of the output from the component may be performed using a bandpass filter synchronized with the excitation signal by centering the bandpass filter near (e.g., within 5% of) the frequency of the excitation signal.

### FIELD OF THE DISCLOSURE

The instant disclosure relates to electronic sensors. More specifically, portions of this disclosure relate to capacitance-based sensors.

### BACKGROUND

Sensing circuits for measuring a capacitance of a component may be used to determine, for example, a capacitance of a speaker or a physical sensor. One example of a capacitance sensor is shown in FIG. 1. FIG. 1 is a block diagram illustrating a capacitance sensing circuit using a transimpedance amplifier (TIA) according to the prior art. A circuit 100 may include a TIA stage 104 coupled to a component 102. An output of the TIA stage 104 is provided to demodulator 106. The demodulated signal is provided to an audio delta-sigma analog-to-digital converter (ADC) 108. The ADC 108 defines a boundary 120 between analog circuitry and digital circuitry. Other digital circuitry may be coupled at node 110 to receive a capacitance value representative of the component 102.

One disadvantage of the TIA-based circuit 100 is that low-frequency 1/f flicker noise affects performance of the circuit 100. Furthermore, performance is limited by noise current introduced by a resistor of the TIA stage 104, a maximum value for the resistor of the TIA stage 104 is determined by swing limitations of subsequent stages, the analog demodulation at stage 106 and signal recovery adds additional power and distortion to the circuit 100, and flicker noise from the audio ADC 108 affects low frequency performance.

Shortcomings mentioned here are only representative and are included simply to highlight that a need exists for improved electrical components, particularly for sensing circuits employed in consumer-level devices, such as mobile phones. Embodiments described herein address certain shortcomings but not necessarily each and every one described here or known in the art. Furthermore, embodiments described herein may present other benefits than, and be used in other applications than, those of the shortcomings described above.

### SUMMARY

Sensing electronics that operate to measure and digitize a capacitance value with improved operation may perform demodulation and may generate the excitation signal with a demodulator and a signal generator in the digital domain. This is unlike TIA-based conventional capacitance sensors described above, which perform demodulation and other tasks in the analog domain. An embodiment of such sensing electronics may include a charge-sense front end with sine wave excitation, a voltage-to-digital conversion block, and a digital demodulator. The component being measured by the sensing electronics may be excited by a high-frequency sine wave excitation. The digitization of the output from the component may be performed using a bandpass filter synchronized with the excitation signal by centering the bandpass filter near (e.g., within 5% of) the frequency of the excitation signal. Using a high-frequency signal, such as between approximately 20 kiloHertz and 1000 kiloHertz, reduces 1/f flicker noise in the signal measured from the component. The high-frequency signal may be outside of the usual audio frequency bands recognized by humans, which are between 20 Hertz and 20 kiloHertz.

This sensing electronics and sensing methods using the high-frequency excitation signal described herein offers several advantages. The charge input stage has an improved signal-to-noise ratio (SNR) and is more immune to interference. The low frequency performance is improved based on reduced flicker noise contribution. Furthermore, performing signal processing in the digital domain reduces noise in the final signal, power consumed in processing the signal, area for the circuits that process the signal, and improved linearity. That is, digital circuits offer several advantages for determining the capacitance based on an output from the component upon application of an excitation signal. The digital processing may be performed in dedicated circuitry or a generic processor, such as a digital signal processor (DSP).

Electronic devices incorporating the sensing circuit, such as for sensing capacitance, described above may benefit from improved capacitance measurements of components of integrated circuits in the electronic devices. For example, a mobile phone may include a speaker or other transducer having an unknown capacitance or changing capacitance. The capacitance of the speaker component may be measured by the sensing circuit and used to control output from the speaker to improve sound quality. The sensing capability provided by a circuit or code executed by a processor may be included in an audio controller. The audio controller may also include an analog-to-digital converter (ADC). The ADC may be used to convert an analog signal, such as an audio signal, to a digital representation of the analog signal. Such an ADC, or a similar digital-to-analog converter (DAC), may be used in electronic devices with audio outputs, such as music players, CD players, DVD players, Blu-ray players, headphones, portable speakers, headsets, mobile phones, tablet computers, personal computers, set-top boxes, digital video recorder (DVR) boxes, home theatre receivers, infotainment systems, automobile audio systems, and the like.

According to one embodiment of the invention, an electronic circuit for measuring and digitizing a capacitance value of a component may include a charge-sense analog front end (AFE) with sine wave excitation to create a voltage signal proportional to input capacitance. The created voltage signal may be provided to a voltage-to-digital conversion block, such as a voltage-mode ADC, for converting the voltage signal to a digital code. The digital code may be provided to a digital demodulator and filtering block for processing the digital code and providing a digital representation of the input capacitance. In this example circuit, the processing of the created voltage is performed in the digital domain after conversion to a digital code by the voltage-to-digital conversion block. In some embodiments, a current signal may be created from the charge-sense analog front end (AFE), instead of a voltage signal. The created current signal may be used to generate a digital code using a current-mode ADC, and that digital code processed similar to the voltage-mode embodiment. In some embodiments, a current signal may be created from the component and provided to a current-mode ADC, and that digital code processed similar to the voltage-mode embodiment.

The foregoing has outlined rather broadly certain features and technical advantages of embodiments of the present invention in order that the detailed description that follows may be better understood. Additional features and advantages will be described hereinafter that form the subject of the claims of the invention. It should be appreciated by those having ordinary skill in the art that the conception and specific embodiment disclosed may be readily utilized as a basis for modifying or designing other structures for carrying out the same or similar purposes. It should also be realized by those having ordinary skill in the art that such equivalent constructions do not depart from the spirit and scope of the invention as set forth in the appended claims. Additional features will be better understood from the following description when considered in connection with the accompanying figures. It is to be expressly understood, however, that each of the figures is provided for the purpose of illustration and description only and is not intended to limit the present invention.

### BRIEF DESCRIPTION OF THE DRAWINGS

For a more complete understanding of the disclosed system and methods, reference is now made to the following descriptions taken in conjunction with the accompanying drawings.

FIG. 1 is a block diagram illustrating a capacitance sensing circuit using a transimpedance amplifier (TIA) according to the prior art.

FIG. 2 is a block diagram illustrating a sensing circuit with digital signal processing according to some embodiments of the disclosure.

FIG. 3 is a flow chart illustrating a method for sensing a capacitance of a component according to some embodiments of the disclosure.

FIG. 4 is a block diagram illustrating a sensing circuit with current-mode operation in the analog domain according to some embodiments of the disclosure.

FIGS. 5A-5C are graphs illustrating outputs within a sensing circuit, such as that of FIG. 2, when measuring a capacitance of a component according to some embodiments of the disclosure.

FIG. 6 is a graph illustrating a bandpass analog-to-digital converter (ADC) response around an excitation frequency according to some embodiments of the disclosure.

FIG. 7 is a graph illustrating a demodulator in-phase output according to some embodiments of the disclosure.

### DETAILED DESCRIPTION

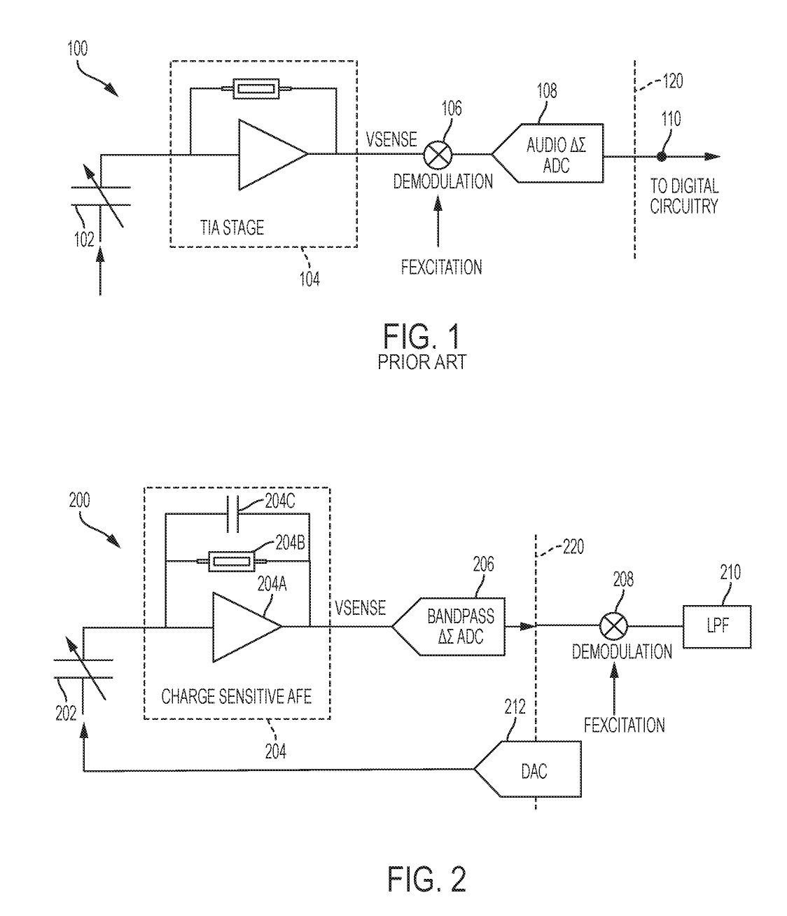

FIG. 2 is a block diagram illustrating a sensing circuit with digital signal processing according to some embodiments of the disclosure. A circuit 200 may include a component 202 having an unknown capacitance. The capacitance may be a fixed unknown that is unknown due to variances in manufacturing of the component 202. The capacitance may also be a changing unknown that is changing during operation of the circuit 200. The capacitance value of the component 202 may be measured with a sensing circuit including components 204, 206, 208, 210, and/or 212. The output of the sensing circuit is a digital representation of the capacitance value for the component 202. The capacitance value may be monitored continuously, such that changes in the capacitance may be detected. In some circuits, the capacitance value may be monitored in real-time or near real-time to detect changes in the capacitance and allow other circuitry to respond to the changes.

The sensing circuit may include a charge-sensitive analog front end (AFE) 204. The AFE 204 may include an amplifier 204A with a feedback loop having a parallel coupled resistor 204B and a capacitor 204C. The AFE 204 may create a voltage sense VSENSE signal that is proportional to a capacitance of the component 202 when excited by an excitation signal from an excitation source. The excitation signal may be a sine wave excitation signal with a high frequency, such as between approximately 20 kiloHertz and 1000 kiloHertz or another frequency outside of the audio band. The created voltage sense VSENSE signal is output from the AFE 204 to additional circuitry in the analog domain for conversion to a digital code. In some embodiments, the circuit 200 may include alterative circuits to the charge-sensitive AFE 204. In other embodiments, the circuit 200 may not include the AFE 204 or an alternative circuit. For example, an output of the component 202 may be coupled directly to analog-to-digital conversion (ADC) circuitry.

An analog value corresponding to the capacitance value of the component 202 may be converted to a digital code for processing in the digital domain. For example, the created voltage sense VSENSE signal from the AFE 204 may be input to an analog-to-digital converter (ADC) 206, such as a bandpass delta-sigma ADC. The ADC 206 may have a bandpass region centered around the excitation frequency. The bandpass region may be a region centered around the excitation frequency extending on either side of the excitation frequency in proportion to the signal bandwidth. The ADC 206 may be a delta-sigma modulator configured for the encoding of narrowband bandpass signals to achieve high signal-to-noise ratios and high resolution at low sampling rates in comparison to lowpass-based ADCs. Example bandpass delta-sigma modulators are described in “Multibit Bandpass Delta-Sigma Modulators Using N-Path Structures” by R. Schreier et al. published by the IEEE and “A Fourth-Order Bandpass Sigma-Delta Modulator” by Stephen A. Jantzi et al. published by the IEEE in the IEEE Journal of Solid-State Circuits, both of which are hereby incorporated by reference in their entirety. An output of the ADC 206 is digital codes that are representative of the capacitance of the component 202. The ADC 206 may define a boundary 220 between an analog domain and a digital domain. Processing performed on an output of the ADC 206 is performed in the digital domain; processing performed prior to conversion in the ADC 206 is performed in the analog domain.

The digital codes representative of the capacitance may be processed to determine the capacitance value of the component 202. For example, the digital codes may be demodulated in demodulator 208 using the excitation frequency to generate a digital representation of the capacitance. The digital representation may be further processed by the low-pass filter (LPF) 210. The LPF 210 may remove out-of-signal band components, including modulation noise. The processing in the digital domain may be performed using digital circuitry and/or a programmable processing circuit such as a digital signal processor (DSP). The demodulator 208 may be matched with the bandpass ADC 206 to allow operation at high frequencies, such as frequencies over 20 kHz.

The excitation signal for performing sensing of the component 202 may be generated by an excitation source based on control from digital circuitry. The digital circuitry may control switching on and off of the excitation signal. The digital circuitry may also or alternatively control the excitation frequency or other aspects of the excitation signal. For example, the digital circuitry may control a digital-to-analog converter (DAC) 212 to function as an excitation source by outputting a sine wave excitation signal with a high frequency. The output of the DAC 212 may be coupled to one terminal of the component 202, and the other terminal of the component 202 coupled to sensing circuitry. In some embodiments, the excitation signal may be applied to a first common mode terminal of the component 202 and the sensing circuitry coupled to a second common mode terminal.

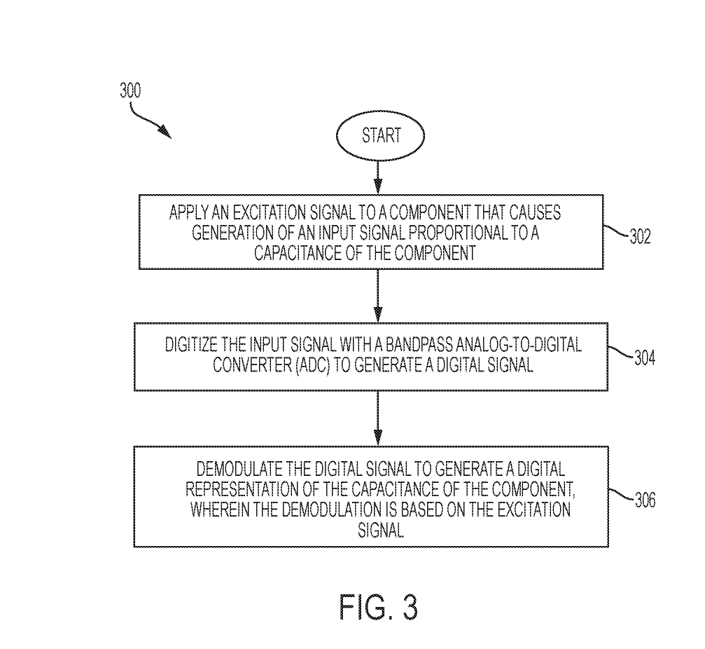

A method for measuring a capacitance of a component is described with reference to FIG. 3. The method of FIG. 3 may be performed using the circuitry illustrated in FIG. 2 or other circuitry for performing the described operations. FIG. 3 is a flow chart illustrating a method for sensing a capacitance of a component according to some embodiments of the disclosure. A method 300 may begin at block 302 with applying an excitation signal to a component that causes the generation of an input signal proportional to a capacitance of the component. The generated input signal is used as an input signal to sensing circuitry for conversion and processing of the input signal to determine the capacitance of the component. At block 304, the input signal is digitized with a bandpass analog-to-digital converter (ADC) to generate a digital signal. The output of the ADC is a boundary for digital domain processing of the signal. Processing between the component and the digitization at block 304 may be performed in the analog domain, while processing after the digitization at block 304 may be performed in the digital domain. At block 306, the digital signal is demodulated to generate a digital representation of the capacitance of the component. The demodulation at block 306 may be based on the excitation signal applied at block 302, such as based on the frequency of the excitation signal.

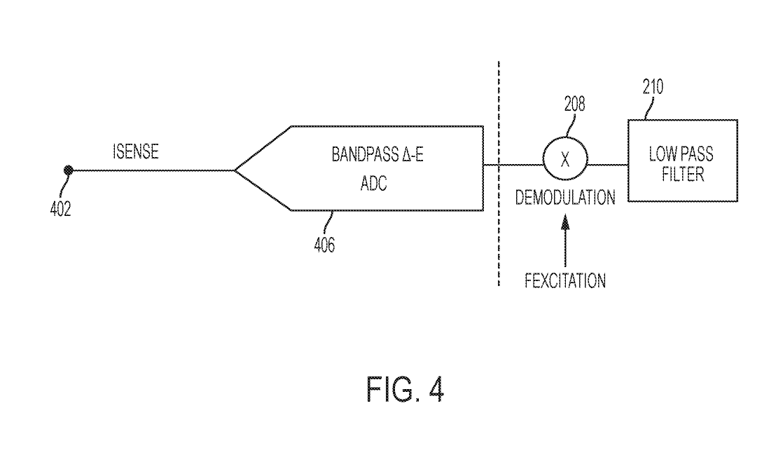

Although some circuitry in the analog domain described above processes voltage sense signals, the capacitance sensing may also be performed using current sense signals, such as shown in FIG. 4. FIG. 4 is a block diagram illustrating a sensing circuit with current-mode operation in the analog domain according to some embodiments of the disclosure. The AFE 204, or other circuitry coupled to the component 202, may be configured to create a current sense signal ISENSE that is proportional to a capacitance of the component 202. When a current signal ISENSE is fed to a current-mode DAC 406, the AFE 204 may be omitted, and instead the current through the component 202 used as input to the ADC 406. The current signal ISENSE may be provided at input node 402 to a current-mode ADC 406, such as a current-mode bandpass delta-sigma ADC. The bandpass ADC 406 receives the analog current signal ISENSE, which is proportional to capacitance of the component 202, and creates a digital code output to the modulator 208. The modulator 208 may process the received digital codes from current-mode ADC 406 in the same manner as when the digital codes are generated with a voltage-mode ADC.

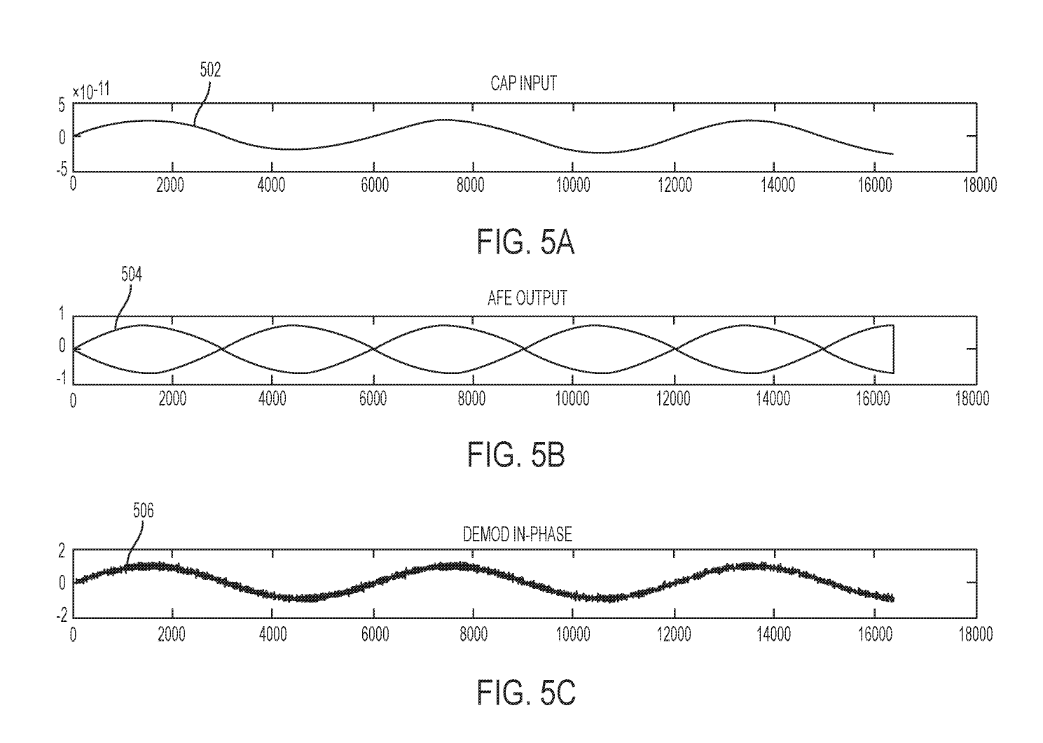

One example operation performed by a sensing circuit according to the embodiment described herein is described with reference to FIGS. 5A-5C. FIGS. 5A-5C are graphs illustrating outputs within a sensing circuit, such as that of FIG. 2, when measuring a capacitance of a component according to some embodiments of the disclosure. The graph of FIG. 5A includes a graph of an output of the component as a function of time. The signal 502 illustrates a capacitance signal output from the component, which may have a pattern similar to a sine wave excitation signal. The graph of FIG. 5B illustrates an output signal 504 of the AFE 204 when the signal 502 is received. The graph of FIG. 5C shows an output signal 506 from a demodulator. The output of graph 506 matches the created input signal shown in graph 502 produced from the component in response to an excitation signal.

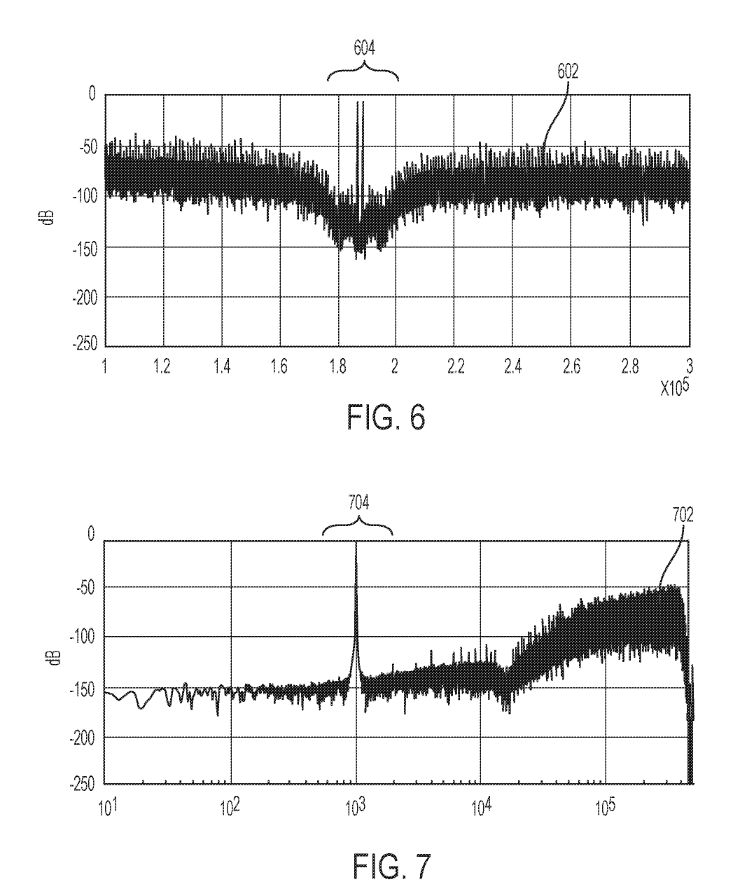

The frequency response of components in the sensing circuit is shown in FIG. 6 and FIG. 7. FIG. 6 is a graph illustrating a bandpass analog-to-digital converter (ADC) response around an excitation frequency according to some embodiments of the disclosure. A graph 602 illustrates a response of a bandpass ADC with a pass region centered at range 604 around an excitation frequency of 187.5 kHz. FIG. 7 is a graph illustrating a demodulator in-phase output according to some embodiments of the disclosure. A graph 702 illustrates a response of the demodulator with a peak output around an input signal frequency of 1 kHz in region 704 with thermal noise throughout the output.

The proposed methods and circuits described herein may solve one or more of the following problems with conventional capacitive sensing: achieving high SNR within constraints of low power and small area for mobile devices; achieving better linearity and total harmonic distortion (THD) performance when compared to existing solutions; achieving better immunity to various interference sources in mobile devices; and/or achieving better low frequency accuracy when compared to existing solutions.

The schematic flow chart diagram of FIG. 3 is generally set forth as a logical flow chart diagram. Likewise, other operations for the circuitry are described without flow charts herein as sequences of ordered steps. The depicted order, labeled steps, and described operations are indicative of aspects of methods of the invention. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagram, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

The operations described above may be performed by a controller configured with any circuit for performing the described operations. Such a circuit may be an integrated circuit (IC) constructed on a semiconductor substrate and include logic circuitry, such as transistors configured as logic gates, and memory circuitry, such as transistors and capacitors configured as dynamic random access memory (DRAM), electronically programmable read-only memory (EPROM), or other memory devices. The logic circuitry may be configured through hard-wire connections or through programming by instructions contained in firmware. Further, the logic circuitry may be configured as a general purpose processor capable of executing instructions contained in software. The firmware and/or software may include instructions that cause the processing of signals described herein to be performed. In some embodiments, the integrated circuit (IC) that is the controller may include other functionality. For example, the controller IC may include an audio coder/decoder (CODEC) along with circuitry for performing the functions described herein. Such an IC is one example of an audio controller. Other audio functionality may be additionally or alternatively integrated with the IC circuitry described herein to form an audio controller.

If implemented in firmware and/or software, functions described above may be stored as one or more instructions or code on a computer-readable medium. Examples include non-transitory computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise random access memory (RAM), read-only memory (ROM), electrically-erasable programmable read-only memory (EEPROM), compact disc read-only memory (CD-ROM) or other optical disk storage, magnetic disk storage or other magnetic storage devices, or any other medium that can be used to store desired program code in the form of instructions or data structures and that can be accessed by a computer. Disk and disc includes compact discs (CD), laser discs, optical discs, digital versatile discs (DVD), floppy disks and Blu-ray discs. Generally, disks reproduce data magnetically, and discs reproduce data optically. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and certain representative advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. For example, where general purpose processors are described as implementing certain processing steps, the general purpose processor may be a digital signal processors (DSPs), a graphics processing units (GPUs), a central processing units (CPUs), or other configurable logic circuitry. As another example, although processing of audio data is described in certain examples, other data may be processed through the filters and other circuitry described above. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding embodiments described herein may be utilized. Accordingly, the appended claims are intended to include within their scope such processes, machines, manufacture, compositions of matter, means, methods, or steps.

What is claimed is:

1. An apparatus, comprising:
a bandpass analog-to-digital converter (ADC) configured to receive an input signal proportional to a capacitance of a component and configured to output a digital signal;
a demodulator coupled to the bandpass ADC and configured to receive the digital signal from the bandpass ADC and configured to output a digital representation of the capacitance of the component; and
an excitation source configured to couple to the component to output an excitation signal to the component that causes generation of the input signal, wherein the excitation source is coupled to the demodulator to synchronize the demodulator with the excitation signal.

2. The apparatus of claim 1, wherein the bandpass ADC is configured to receive an input current signal as the input signal.

3. The apparatus of claim 1, wherein the bandpass ADC is configured to receive an input voltage signal as the input signal.

4. The apparatus of claim 3, further comprising a charge sense front end coupled to the bandpass ADC and configured to couple to the component to generate the input voltage signal based on the capacitance of the component.

5. The apparatus of claim 1, wherein the excitation source comprises a sine wave excitation source configured to couple to the component and apply a sine wave to the component for measurement of the capacitance of the component, wherein the demodulator is coupled to the sine wave excitation source and configured to synchronize with the sine wave.

6. The apparatus of claim 5, wherein the sine wave excitation source is configured to generate a sine wave with a frequency between approximately 20 kiloHertz and 1000 kiloHertz.

7. The apparatus of claim 1, further comprising a low-pass filter (LPF) coupled to the demodulator.

8. The apparatus of claim 1, further comprising a transducer, wherein the transducer is coupled to the bandpass ADC, and wherein the capacitance of the component is a capacitance of the transducer.

9. A method, comprising:
applying an excitation signal to a component that causes generation of an input signal proportional to a capacitance of the component;
digitizing the input signal with a bandpass analog-to-digital converter (ADC) to generate a digital signal; and
demodulating the digital signal with a demodulator to generate a digital representation of the capacitance of the component, wherein the demodulating is based, at least in part, on the excitation signal.

10. The method of claim 9, wherein the step of digitizing an input signal comprises digitizing an input current signal.

11. The method of claim 9, wherein the step of digitizing an input signal comprises digitizing an input voltage signal.

12. The method of claim 11, further comprising sensing, with a charge sense front end, the component to generate the input voltage signal.

13. The method of claim 9, further comprising applying a sine wave to the component for measurement of the capacitance of the component.

14. The method of claim 13, wherein the sine wave has a frequency between approximately 20 kiloHertz and 1000 kiloHertz.

15. The method of claim 9, further comprising low-pass filtering the digital representation generated by demodulating the digital signal.

16. The method of claim 9, further comprising determining a capacitance of a transducer based, at least in part, on the digital representation of the capacitance of the component.

17. An apparatus, comprising:
a controller configured to perform steps comprising:
applying an excitation signal to a component that causes generation of an input signal proportional to a capacitance of the component;
digitizing the input signal with a bandpass analog-to-digital converter (ADC) to generate a digital signal; and
demodulating the digital signal with a demodulator to generate a digital representation of the capacitance of the component, wherein the demodulating is based, at least in part, on the excitation signal.

18. The apparatus of claim 17, wherein the controller is configured to digitize the input signal by digitizing an input current signal.

19. The apparatus of claim 17, wherein the controller is configured to digitize the input signal by digitizing an input voltage signal, wherein the apparatus further comprises a charge sense front end coupled to the controller and configured to couple to the component to generate the input voltage signal based on the capacitance of the component.

20. The apparatus of claim 17, wherein the apparatus further comprises a transducer coupled to the controller, and wherein the controller is further configured to determine a capacitance of the transducer based, at least in part, on the digital representation of the capacitance of the component.
